(19) United States
(12) Patent Application Publication
(10) Pub. No.: US 2008/0242054 A1
(43) Pub. Date: Oct. 2, 2008

(54) Dicing and drilling of wafers

(76) Inventors: Andy Antonelli, Phoenix, AZ (US); Eric J. Li, Chandler, AZ (US); Sergei Voronov, Chandler, AZ (US)

Correspondence Address: CAVEN & AGHEVLI;c/o INTELLEVATE, LLC, P.O. BOX 52050, MINNEAPOLIS, MN, 55402, US

(21) Appl. No.: 11/729,492

(22) Filed: Mar. 29, 2007

(51) Int. Cl. H01L 21/78; B23K 26/38

(52) U.S. Cl. 438/463; 219/121.67; 257/E21.599

(57) ABSTRACT

Methods and apparatus to dicing and/or drilling of wafers are described. In one embodiment, an electromagnetic radiation beam (e.g., a relatively high intensity, ultra-short laser beam) may be used to dice and/or drill a wafer. Other embodiments are also described.

### BACKGROUND

The present disclosure generally relates to the field of electronics. More particularly, an embodiment of the invention generally relates to dicing and/or drilling of wafers.

Integrated circuit devices are generally constructed by providing various layers of material that are deposited on wafers. During the manufacturing process of integrated circuits, wafers may be cut into dies. Furthermore, holes may need to be drilled in the wafers. As integrated circuit dies become smaller, accurate dicing and drilling of the wafers becomes more paramount to successful manufacturing of electronic devices.

### BRIEF DESCRIPTION OF THE DRAWINGS

The detailed description is provided with reference to the accompanying figures. In the figures, the left-most digit(s) of a reference number identifies the figure in which the reference number first appears. The use of the same reference numbers in different figures indicates similar or identical items.

FIG. 1 illustrates a block diagram of a system 100 that may be used for dicing and/or drilling wafers, in accordance with some embodiments of the invention.

FIG. 2 illustrates a top view of results of utilizing a high energy, ultra-short laser at various intensities on a wafer, according to some embodiments of the invention.

FIGS. 3A and 3B illustrate cross-sectional scanning electron microscopy (SEM) micrographs of trenches produced by a high energy, ultra-short laser, according to some embodiments.

FIG. 4 illustrates an embodiment of a profile that may be used for a high energy, ultra-short laser beam, in accordance with one embodiment.

FIG. 5 illustrates a block diagram of a method according to an embodiment.

### DETAILED DESCRIPTION

In the following description, numerous specific details are set forth in order to provide a thorough understanding of various embodiments. However, various embodiments of the invention may be practiced without the specific details. In other instances, well-known methods, procedures, components, and circuits have not been described in detail so as not to obscure the particular embodiments of the invention. Further, various aspects of embodiments of the invention may be performed using various means, such as integrated semiconductor circuits (“hardware”), computer-readable instructions organized into one or more programs (“software”), or some combination of hardware and software. For the purposes of this disclosure reference to “logic” shall mean either hardware, software, or some combination thereof.

Reference in the specification to “one embodiment” or “an embodiment” means that a particular feature, structure, or characteristic described in connection with the embodiment may be included in at least an implementation. The appearances of the phrase “in one embodiment” in various places in the specification may or may not be all referring to the same embodiment.

Also, in the description and claims, the terms “coupled” and “connected,” along with their derivatives, may be used. In some embodiments of the invention, “connected” may be used to indicate that two or more elements are in direct physical or electrical contact with each other. “Coupled” may mean that two or more elements are in direct physical or electrical contact. However, “coupled” may also mean that two or more elements may not be in direct contact with each other, but may still cooperate or interact with each other.

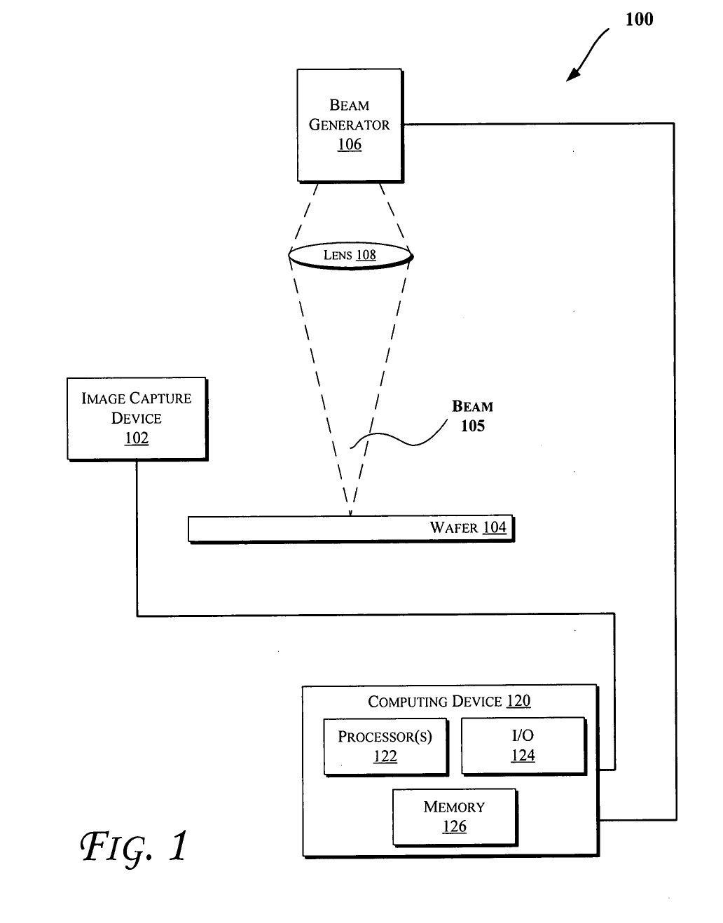

Some of the embodiments discussed herein (such as the embodiments discussed with reference to FIGS. 1-5) may utilize an electromagnetic radiation beam (e.g., a laser beam) for dicing and/or drilling of wafers (such as thin wafers). In an embodiment, wafers may be drilled to provide vias that may electrically couple various layers of material deposited on the wafers. In one embodiment, a high energy, ultra-short laser source allows access to non-linear optical absorption which may be leveraged to create high aspect ratio trenches and/or holes in a thin wafer. This effect, e.g., together with reduced heat affected zone of ultra-fast optical pulses, may enable an improved dicing and/or via drilling process for thin wafers.

More particularly, FIG. 1 illustrates a block diagram of a system 100 that may be used for dicing and/or drilling wafers, in accordance with some embodiments of the invention. As shown in FIG. 1, the system 100 may include an image capture device 10, e.g., to capture one or more images of a wafer 104. The wafer 104 may be patterned by a pattern generating tool (not shown). The device 102 may capture an image of the wafer 104 after (or while) a beam 105 (e.g., generated by a beam generator 106) is used to cut (e.g., to dice, for example) the wafer 104 and/or drill one or more holes into the wafer 104.

In an embodiment, the generator 106 may be any type of an electromagnetic beam generator such as a laser source capable of producing an optical pulse train with: (a) temporal duration of less than about 20 ρs; (b) pulse energy of greater than about 1 μJ; and/or (c) a repetition rate between about 10 kHz and about 10 MHz. Other types of a laser source may also be utilized. Additionally, a laser pulse of Gaussian spatial beam profile may be focused to a sufficiently high intensity to observe non-linear absorption in one embodiment. For example, the system 100 may optionally include a lens 108 to focus the beam generated by the beam generator 106. Also, the lens 108 may include more than a single lens in some embodiments.

As illustrated in FIG. 1, the system 100 may additionally include a computing device 120, e.g., to control some or all of the operations performed by the system 100, as discussed herein, for example, with reference to FIG. 5. Alternatively, a general-purpose computing device may be used instead of our in addition to the computing device 120, e.g., to control some or all of the operations performed by the system 100 and/or to perform analysis regarding the cutting and/or drilling of the wafer 104. The computing device 120 may include one or more processors 122, an input/output (I/O) module 124, and/or a memory 126 (which may be a volatile and/or nonvolatile memory). For example, the I/O module 124 may communicate with various components of the system 100, while the processors 122 may process the communicated data and the memory 126 may store the communicated data. As shown in FIG. 1, the computing device 120 may control and/or communicate with the beam generator 106 and/or the image capture device 102. For example, the computing device 120 may cause the beam generator 106 to generate a beam at a select energy, wavelength, frequency, for a certain time period, etc. Moreover, the computing device 120 may cause the image capture device 102 to capture an image of the wafer 104 for further processing in some embodiments.

Generally, some current ablation techniques may only access top layers of a wafer. Singulation of a semiconductor wafer and drilling through several semiconductor layers and the silicon substrate may not be feasible using traditionally focused laser beams with relatively long pulse duration, in part, because even loose focusing geometry may not preserve the same intensity at different depths in the wafer. In addition, a relatively long nanosecond laser pulse may create thermal impact and/or mechanical damage to the semiconductor wafer. In an embodiment, via drilling may be performed using deep reactive ion etching (DRIE). Furthermore, an external lithography processing system may be used to define the via locations. Accordingly, in accordance with an embodiment, DRIE may be combined with the high energy, ultra-short laser beam discussed herein (e.g., beam 105 discussed with reference to FIG. 1) to drill holes and/or dice wafers.

Moreover, in an embodiment, lowering the pulse width of the beam 105 to a high energy, ultra-short time scale (order of picoseconds for example), e.g., from a nanosecond pulse width, may relatively decrease the thermal diffusion length and shrink the so-called “heat affected zone” (HAZ). One reason for this substitution (e.g., a high energy, ultra-short laser beam for a nanosecond laser beam) is that the thermal diffusion time generally scales directly with the optical pulse duration. A reduction in HAZ may be beneficial. More particularly, in dicing applications, the HAZ defines the effective kerf width and may be relatively large on the order of 100 μm which may be equal to some street sizes and potentially larger than street designs of coming generations. When dicing or drilling a via in a thin wafer, the HAZ may take on a three-dimensional character creating recast material both on the front side and backside of the wafer leading to various defect modes which may down select certain process options.

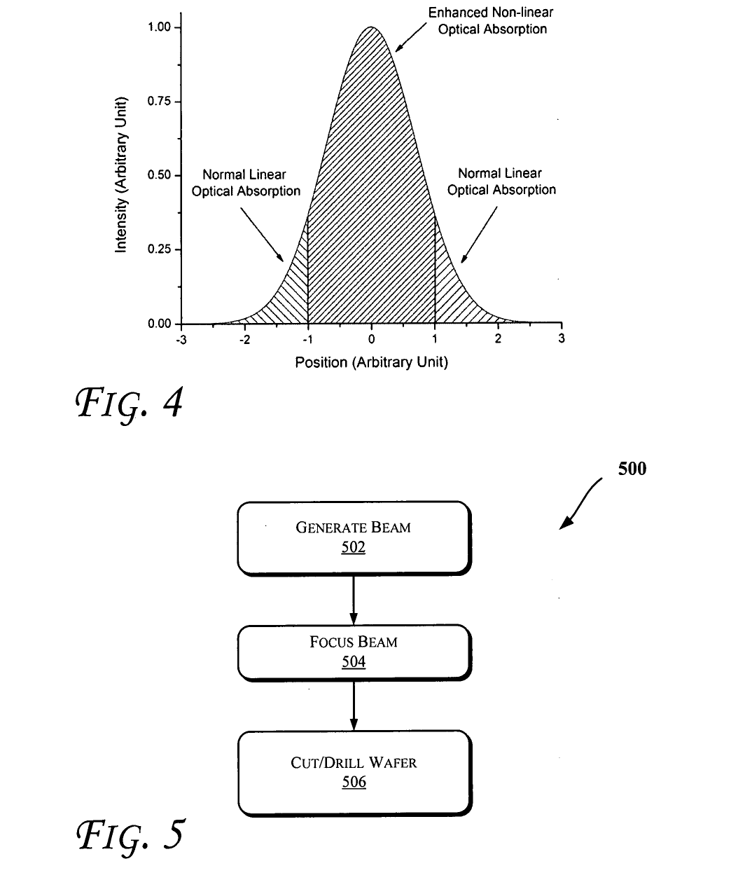

Additionally, in an embodiment, there may be one feature of high energy, ultra-short laser pulses that may be leveraged to further improve the dicing and/or via drilling process. Specifically, the intensity of high energy, ultra-short pulses may be much larger than nanosecond pulses as a result of their very short temporal extent. High intensity may make it possible to observe non-linear optical effects such as two- or multi-photon absorption. In this process, multiple photons take part in the creation of a given electronic excitation in a material. If the high energy, ultra-short optical pulse is delivered to the sample as a beam of Gaussian spatial profile (such as the profile shown in FIG. 4) and the laser intensity is great enough, then linear absorption may occur across the entire beam, and non-linear absorption may occur at the center of the beam leading a marked enhancement in the ablation rate.

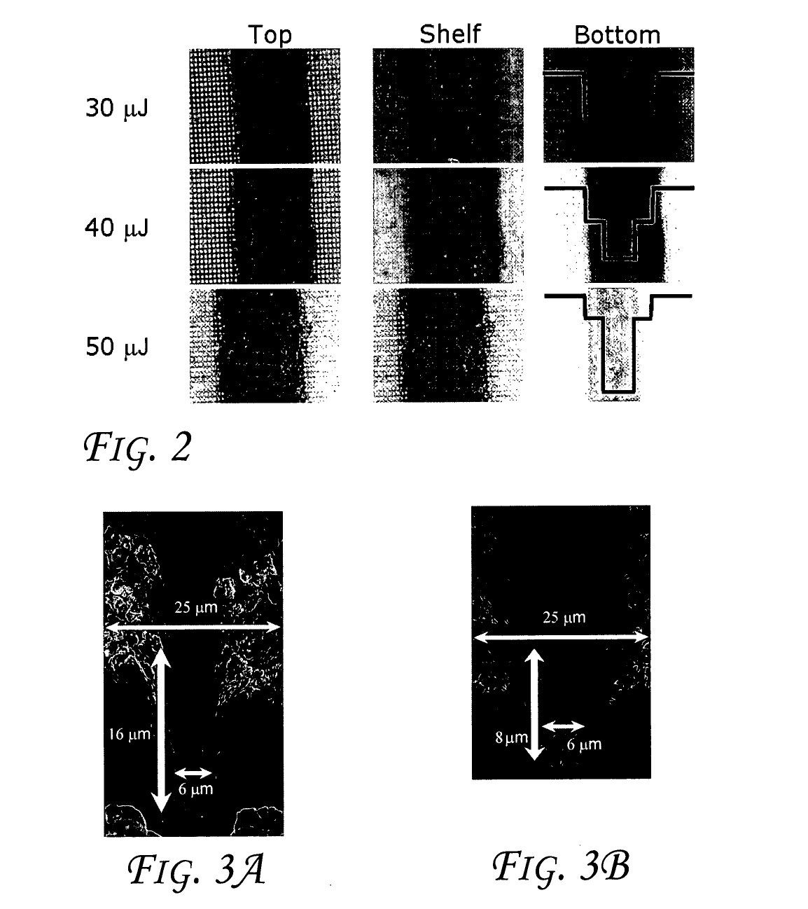

Referring to FIG. 2, one may create relatively deep and yet relatively narrow trenches, i.e., high aspect ratio, by utilizing beam 105 of FIG. 1. The same methodology may be applied to the creation of high aspect ratio vias. More particularly, FIG. 2 illustrates a top view of results of utilizing a high energy, ultra-short laser at various intensities on a wafer, according to some embodiments of the invention. In an embodiment, the results shown in FIG. 2 may be obtained by using a high energy, ultra-short laser beam (e.g., such as the beam 105) that is focused to an optical spot size with a diameter of about 25 μm (and/or Gaussian in spatial extent, for example). The images shown in FIG. 2 may be captured (e.g., by using the image capture device 102 such as discussed with reference to FIG. 1) using about 1064 nm, a repetition rate of about 30 kHz, and an overlap of about 97.5%. Similar results may also be found at about 532 nm and about 355 nm at other repetition rates and overlaps.

Referring to FIGS. 3A and 3B, cross-sectional scanning electron microscopy (SEM) micrographs of a focus ion-beam milled region of a high intensity, ultra-short laser machined trench are illustrated, according to some embodiments. In accordance with one embodiment, the images of FIGS. 3A-3B illustrate that ablation volume may be the non-linear function of applied laser intensity for high energy, ultra-short laser processing. More particularly, FIG. 3A illustrates a high aspect groove cut into the street of a silicon die using a high energy, ultra-short laser operating with about 10 ρs pulse width at about 532 nm with a repetition rate of about 30 kHz. The optical spot size at focus may have a diameter of about 25 μm, and may further be Gaussian in an embodiment. The overlap may be at about 97.5%. FIG. 3B illustrates the identical laser conditions as FIG. 3A but with about two times lower intensity. As may be seen by comparing FIGS. 3A and 3B, the lower intensity used for the results of FIG. 3B may render a similar kerf width (e.g., of about 25 μm) with a shorter depth of about 8 μm.

FIG. 4 illustrates an embodiment of a profile that may be used for a high energy, ultra-short laser beam, in accordance with one embodiment. For example, the beam 105 of FIG. 1 may have the profile shown in FIG. 4 in accordance with one embodiment. Other beam profiles may also be used.

FIG. 5 illustrates a block diagram of an embodiment of a method 500 to cut and/or drill a wafer. In an embodiment, various components discussed with reference to FIGS. 1-4 may be utilized to perform one or more of the operations discussed with reference to FIG. 5. For example, the method 500 may be used to provide cut the wafer 104 of FIG. 1.

Referring to FIGS. 1-5, at an operation 502, an electromagnetic radiation beam may be generated (e.g., beam 105 may be generated by the generator 106). As discussed with reference to FIG. 4, the generated beam may have a Gaussian profile in an embodiment. At an operation 504, the beam may be focused (e.g., by the lens 108). At an operation 506, the beam may be used to cut and/or drill a semiconductor wafer (e.g., such as a wafer 104).

In some embodiments, high energy, ultra-short laser pulses (e.g., generated by the beam generator 106 of FIG. 1) may create a relatively small heat affected zone which may limit the recast region and/or generate less damage at the edge of the silicon die. Further, for dicing applications, less silicon damage may lead to greater die break strength and/or the relatively smaller heat affected zone may lead to a smaller effective kerf width. Non-linear effects may also become possible when using high energy, ultra-short optical pulses, in part, because of the great intensity afforded by the short pulse width. When using a Gaussian beam profile (such as the profile shown in FIG. 4) at a sufficiently high intensity, non-linear optical absorption may enable a higher rate of ablation at the center of the beam because of the greater intensity in that portion. Enhanced ablation in turn allows for the formation of features with much smaller size than the corresponding optical spot size.

In various embodiments of the invention, the operations discussed herein, e.g., with reference to FIGS. 1-5, may be implemented through hardware (e.g., logic circuitry), software, firmware, or combinations thereof, which may be provided as a computer program product, e.g., including a machine-readable or computer-readable medium having stored thereon instructions (or software procedures) used to program a computer to perform a process discussed herein. The machine-readable medium may include a storage device such as the memory 126 of FIG. 1. Additionally, one or more of the operation of components of the system 100 of FIG. 1 may be controlled by the machine-readable medium.

Additionally, such computer-readable media may be downloaded as a computer program product, wherein the program may be transferred from a remote computer (e.g., a server) to a requesting computer (e.g., a client) by way of data signals embodied in a carrier wave or other propagation medium via a communication link (e.g., a bus, a modem, or a network connection). Accordingly, herein, a carrier wave shall be regarded as comprising a machine-readable medium.

Thus, although embodiments of the invention have been described in language specific to structural features and/or methodological acts, it is to be understood that claimed subject matter may not be limited to the specific features or acts described. Rather, the specific features and acts are disclosed as sample forms of implementing the claimed subject matter.

What is claimed is:

1. An apparatus comprising:
a beam generator to generate a laser beam having a temporal duration of less than about 20 ρs and a pulse energy of greater than about 1 μJ,
wherein the beam is to modify a wafer.

2. The apparatus of claim 1, wherein the beam has a repetition rate between about 10 kHz and about 10 MHz.

3. The apparatus of claim 1, wherein the beam is to dice the wafer into one or more dies.

4. The apparatus of claim 1, wherein the beam is to drill one or more holes in the wafer.

5. The apparatus of claim 4, wherein the one or more holes are used as vias.

6. The apparatus of claim 1, wherein the beam is to cut one or more trenches in the wafer.

7. The apparatus of claim 1, wherein the beam has a substantially Gaussian profile.

8. The apparatus of claim 1, further comprising a lens to focus the beam.

9. The apparatus of claim 1, further comprising a computing device to control the beam generator.

10. The apparatus of claim 1, further comprising an image capture device to capture one or more images of the wafer.

11. A method comprising:
generating a laser beam having a temporal duration of less than about 20 ρs and a pulse energy of greater than about 1 μJ; and
modifying a wafer with the beam.

12. The method of claim 11, wherein the beam has a repetition rate between about 10 kHz and about 10 MHz.

13. The method of claim 11, wherein modifying the wafer comprises dicing the wafer into one or more dies.

14. The method of claim 11, wherein r modifying the wafer comprises one or more of:
drilling one or more holes in the wafer; or
cutting one or more trenches in the wafer.

15. The method of claim 11, further comprising focusing the laser beam.
